(19) United States
(12) Patent Application Publication
(10) Pub. No.: US 2010/0283153 A1
(43) Pub. Date: Nov. 11, 2010

(54) Ohmic Contact Having Silver Material

(75) Inventor: Chih-Hung Wu, Longtan Shiang (TW)

Correspondence Address: Jackson Intellectual Property Group PLLC, 106 Starvale Lane, Shipman, VA, 22971, US

(73) Assignee: ATOMIC ENERGY COUNCIL-INSTITUTE OF NUCLEAR ENERGY RESEARCH, Taoyuan (TW)

(21) Appl. No.: 12/651,991

(22) Filed: Jan. 4, 2010

(30) Foreign Application Priority Data
May 7, 2009 (TW) 098115083

(51) Int. Cl. H01L 23/48

(52) U.S. Cl. 257/745; 257/E23.01

(57) ABSTRACT

An ohmic contact is fabricated. The ohmic contact has low electric resistivity and high thermal conductivity. The materials for fabricating the ohmic contact include silver. Thus, equipments for fabricating the ohmic contact are compatible to modern generally used equipments.

### FIELD OF THE INVENTION

The present invention relates to an ohmic contact; more particularly, relates to an ohmic contact having low electric resistivity and high thermal conductivity, which contains silver and is compatible with modern arts to be fabricated with low cost.

### DESCRIPTION OF THE RELATED ARTS

Almost every semiconductor device needs an ohmic contact having low resistance to optimize its performance. It is because a contact having high resistance will produce too much heat and thus weaken the device. Generally, the ohmic contact for gallium arsenide (GaAs) semiconductor is made of an alloy of AuGe/Ni and the contact is made through anneal at a temperature between 400° C. and 500° C.

But, the ohmic contact is made with gold, not silver having lower electric conductivity and higher heat conductivity. In addition, gold is more expensive than silver, which make the production cost higher. Hence, the prior art does not fulfill all users' requests on actual use.

### SUMMARY OF THE INVENTION

The main purpose of the present invention is to provide an ohmic contact having low electric resistivity and high thermal conductivity, which contains silver and is compatible with modern arts to be fabricated with low cost.

To achieve the above purpose, the present invention is an ohmic contact containing silver, comprising an ohmic contact and an n-type III-V compound semiconductor layer, where the ohmic contact comprises a nickel (Ni) layer, a germanium (Ge) layer, a silver (Ag) layer, a palladium (Pd) or platinum (Pt) layer, and a thick metal layer; and; where the Ni layer, the Ge layer, the Ag layer, the Pd or Pt layer and the thick metal layer are sequentially stacked on the n-type III-V compound semiconductor layer; and where the ohmic contact is obtained by being processed through annealing. Accordingly, a novel ohmic contact containing silver is obtained.

### BRIEF DESCRIPTIONS OF THE DRAWINGS

The present invention will be better understood from the following detailed description of the preferred embodiment according to the present invention, taken in conjunction with the accompanying drawings, in which

FIG. 1 is the sectional view showing the structure of the preferred embodiment according to the present invention; and

FIG. 2 is the view showing the analysis of electric resistivity and thermal conductivity.

### DESCRIPTION OF THE PREFERRED EMBODIMENT

The following description of the preferred embodiment is provided to understand the features and the structures of the present invention.

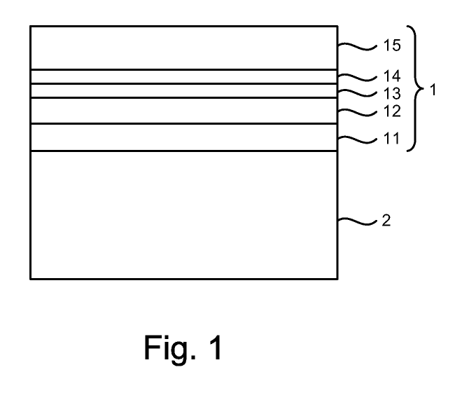

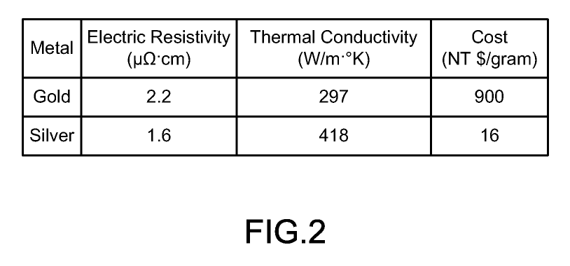

Please refer to FIG. 1 and FIG. 2, which are a sectional view showing a structure of a preferred embodiment according to the present invention; and a view showing an analysis of electric resistivity and thermal conductivity. As shown in the figures, the present invention is an ohmic contact containing silver, comprising an ohmic contact 1 and a n-type III-V compound semiconductor layer 2, where the ohmic contact 1 comprises a nickel (Ni) layer 11, a germanium (Ge) layer 12, a silver (Ag) layer 13, a palladium (Pd) or platinum (Pt) layer 14, and a thick metal layer 15; and the Ni layer 11, the Ge layer 12, the Ag layer 13, the Pd or Pt layer 14 and the thick metal layer 15 are sequentially stacked on the n-type III-V compound semiconductor layer 2. Therein, the ohmic contact 1 obtains a structure body by being processed through annealing at a temperature between 300° C. and 500° C.; the Ni layer 11 has a thickness between 1 nanometer (nm) and 20 nm; the Ge layer 12 has a thickness between 1 nm and 50 nm; the Ag layer 13 has a thickness between 5 nm and 200 nm; and the Pd layer 14 has a thickness between 20 nm and 200 nm (or, the Pt layer has a thickness between 10 nm and 200 nm.) Thus, a novel ohmic contact containing silver is obtained.

At first, a Ni layer 11, a Ge layer 12, an Ag layer 13, a Pd or Pt layer 14 and a thick metal layer 15 of an ohmic contact 1 are sequentially deposed on an n-type III-V compound semiconductor layer through evaporation deposition or electroplating deposition, where the n-type III-V compound semiconductor layer 2 is a gallium arsenide (GaAs) layer.

Thus, through annealing, the ohmic contact 1 obtains low electric resistivity and high thermal conductivity. The low electric resistivity and the high thermal conductivity of the ohmic contact 1 are obtained by controlling thicknesses of the metal layers coordinated with the annealing temperature, where a thickness ratio of the Ag layer 13 to the Ge layer 12 lies between 7 and 8 and the annealing temperature is 400° C. In the other hand, the n-type III-V compound semiconductor layer 2 is made of light emitting diode (LED), laser diode, solar cell or transistor.

In the present invention, the ohmic contact contains silver, which has good electric conductivity and thermal conductivity and is compatible with modern arts. Furthermore, silver is cheaper than gold (as shown in FIG. 2) so the ohmic contact fabricated is cheaper.

To sum up, the present invention is an ohmic contact containing silver, where the ohmic contact has low electric resistivity and high thermal conductivity; and the present invention contains silver and is compatible with modern arts to be fabricated with low cost.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. An ohmic contact containing silver, comprising
an ohmic contact, said ohmic contact comprising a nickel (Ni) layer, a germanium (Ge) layer, a silver (Ag) layer, a palladium (Pd) or platinum (Pt) layer, and a thick metal layer; and
an n-type III-V compound semiconductor layer,
wherein said Ni layer, said Ge layer, said Ag layer, said Pd or Pt layer and said thick metal layer are sequentially stacked on said n-type III-V compound semiconductor layer;
wherein said ohmic contact is obtained by being processed through annealing; and
wherein a thickness ratio of said Ag layer to said Ge layer lies between 7 and 8.

2. The contact according to claim 1, wherein said n-type III-V compound semiconductor layer is a gallium arsenide (GaAs) layer.

3. The contact according to claim 1,
wherein said Ni layer has a thickness between 1 nanometer (nm) and 20 nm.

4. The contact according to claim 1,
wherein said Ge layer has a thickness between 1 nm and 50 nm.

5. The contact according to claim 1,
wherein said Ag layer has a thickness between 5 nm and 200 nm.

6. The contact according to claim 1,
wherein said Pd layer has a thickness between 20 nm and 200 nm.

7. The contact according to claim 1,
wherein said Pt layer has a thickness between 10 nm and 200 nm.

8. The contact according to claim 1,
wherein said annealing has a temperature between 300 Celsius degrees (° C.) and 500° C.

9. The contact according to claim 1,
wherein said n-type III-V compound semiconductor layer is made of a material selected from a group consisting of light emitting diode (LED), laser diode, solar cell and transistor.
